(19) United States
(12) Patent Application Publication
(10) Pub. No.: US 2022/0406923 A1
(43) Pub. Date: Dec. 22, 2022

(54) BILAYER METAL DICHALCOGENIDES, SYNTHESES THEREOF, AND USES THEREOF

(71) Applicant: Honda Motor Co., Ltd., Tokyo (JP)

(72) Inventors: Avetik Harutyunyan, Santa Clara, CA (US); Xufan Li, Fremont, CA (US)

(21) Appl. No.: 17/350,384

(22) Filed: Jun. 17, 2021

(51) Int. Cl. H01L 29/76; H01L 29/06; H01L 29/24; H01L 21/02

(52) U.S. Cl. CPC H01L 29/7606; H01L 29/0665; H01L 29/24; H01L 21/02568

(57) ABSTRACT

The present disclosure generally relates to bilayer metal dichalcogenides, to processes for forming bilayer metal dichalcogenides, and to uses of bilayer metal dichalcogenides in devices for quantum electronics. In an aspect, a device is provided. The device includes a gate electrode, a substrate disposed over at least a portion of the gate electrode, and a bottom layer including a first metal dichalcogenide, the bottom layer disposed over at least a portion of the substrate. The device further includes a top layer including a second metal dichalcogenide, the top layer disposed over at least a portion of the bottom layer, the first metal dichalcogenide and the second metal dichalcogenide being the same or different. The device further includes a source electrode and a drain electrode disposed over at least a portion of the top layer.

### FIELD

The present disclosure generally relates to bilayer metal dichalcogenides, to processes for forming bilayer metal dichalcogenides, and to uses of bilayer metal dichalcogenides in devices for quantum electronics, e.g., quantum computing, quantum sensing, and quantum communication.

### BACKGROUND

Quantum dots are nanoscale semiconductor particles that can transport electrons. Quantum dots display optical and electronic properties that differ from larger particles due to quantum mechanics. Traditionally, quantum dots have been attractive in optics and energy applications due to their size-dependent energy bandgap resulting from confinement to nanometer length scales in three dimensions. As quantum computing and information processing become increasingly important, quantum dots, becoming the platform for various qubits, the building block of quantum information. The emergence of thin, two-dimensional (2D) transitional metal chalcogenide (TMD) fabricated to a width on the nanoscale level presents a new family of quantum dot nanostructures.

Quantum dots of TMDs have been synthesized through solution-based methods. However, the lack of size distribution and ability to manipulate individual quantum dots remains challenging by such fabrication methods. Lithography patterning and electrostatic gating methods have also been utilized to fabricate individual quantum dots of 2D TMDs. However, such methods have the tendency to introduce contamination. Moreover, forming small (sub-20 nm or sub-10 nm) quantum dots is difficult using either lithography patterning or electrostatic gating. Further, devices that include such small-sized quantum dots cannot be manufactured due to the aforementioned challenges in their syntheses.

There is a need for new and improved bilayer metal dichalcogenides and processes for forming bilayer metal dichalcogenides that overcome one or more of the aforementioned deficiencies.

### SUMMARY

The present disclosure generally relates to bilayer metal dichalcogenides, to processes for forming bilayer metal dichalcogenides, and to uses of bilayer metal dichalcogenides in devices for quantum electronics, e.g., quantum computing, quantum sensing, and quantum communication.

In an aspect, a device is provided. The device includes a gate electrode, a substrate disposed over at least a portion of the gate electrode, and a bottom layer including a first metal dichalcogenide, the bottom layer disposed over at least a portion of the substrate. The device further includes a top layer including a second metal dichalcogenide, the top layer disposed over at least a portion of the bottom layer, the first metal dichalcogenide and the second metal dichalcogenide being the same or different. The device further includes a source electrode and a drain electrode disposed over at least a portion of the top layer.

In another aspect, a process is provided. The process includes positioning a substrate in a chamber, and thermally depositing a salt, a metal particle, thermally depositing a salt, a metal particle, a first precursor comprising Mo, W, or a combination thereof, and a second precursor comprising S, Se, Te, or combinations thereof on the substrate to form a multilayer structure. The multilayer structure includes a bottom layer disposed over at least a portion of the substrate, the bottom layer including a first metal dichalcogenide, and a top layer disposed over at least a portion of the bottom layer, the top layer including a second metal dichalcogenide.

In another aspect, a process is provided. The process includes cooling a device at a temperature of about 1 K to about 80 K, the device including a gate electrode, a substrate disposed over at least a portion of the gate electrode, a bottom layer comprising a first metal dichalcogenide, the bottom layer disposed over at least a portion of the substrate, a top layer comprising a second metal dichalcogenide, the top layer disposed over at least a portion of the bottom layer, the first metal dichalcogenide and the second metal dichalcogenide being the same or different, and a source electrode and a drain electrode disposed over at least a portion of the top layer. The process further includes applying a voltage to the gate electrode to control a flow of an electron between one or more of the source electrode, the drain electrode, the bottom layer, or the top layer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, for the disclosure may admit to other equally effective aspects.

FIG. 1A is a side view of an example bilayer structure according to at least one aspect of the present disclosure.

FIG. 1B is a top view of the bilayer structure shown in FIG. 1A.

FIG. 1C is an illustration of an example zigzag edge configuration and an example armchair-edge configuration of nanoribbons according to at least one aspect of the present disclosure.

FIG. 1D is an illustration of an example bilayer structure having an AA′ (2H) stacking configuration according to at least one aspect of the present disclosure.

FIG. 1E is an illustration of an example bilayer structure having an AB (3R) stacking configuration according to at least one aspect of the present disclosure.

FIG. 1F is an illustration of an example bilayer structure having a twisted stacking configuration according to at least one aspect of the present disclosure.

FIG. 2 is an example apparatus used to form metal dichalcogenide bilayer structures according to at least one aspect of the present disclosure.

FIG. 3 shows selected operations of an example process for forming metal dichalcogenide bilayer structures according to at least one aspect of the present disclosure.

FIG. 4A is a top view of an example multilayer structure formed during the process of FIG. 3 according to at least one aspect of the present disclosure.

FIG. 4B is a cross-sectional view of the multilayer structure shown in FIG. 4A according to at least one aspect of the present disclosure.

FIG. 4C is a top view of an example multilayer structure after converting portions of the bottom layer of the multilayer structure to a removable layer according to at least one aspect of the present disclosure.

FIG. 4D is a cross-sectional view of the multilayer structure shown in FIG. 4C according to at least one aspect of the present disclosure.

FIG. 4E is a top view of an example bilayer structure disposed over a substrate after removing the etchable layer according to at least one aspect of the present disclosure.

FIG. 4F is a cross-sectional view of the bilayer structure shown in FIG. 4E according to at least one aspect of the present disclosure.

FIG. 4G is a top view of an example multilayer structure after converting the top layer and portions of the bottom layer of the multilayer structure to removable layers according to at least one aspect of the present disclosure.

FIG. 4H is a cross-sectional view of the multilayer structure shown in FIG. 4G according to at least one aspect of the present disclosure.

FIG. 4I is a top view of an example single layer structure disposed over a substrate after removing the removable layers according to at least one aspect of the present disclosure.

FIG. 4J a cross-sectional view of the single layer structure shown in FIG. 4I according to at least one aspect of the present disclosure.

FIG. 5 is an example device incorporating an example bilayer structure according to at least one aspect of the present disclosure.

FIG. 6A is an exemplary high-angle annular dark-field scanning transmission electron microscopy (HAADF-STEM) image showing the bilayer having an AA′ (2H) stacking configuration according to at least one aspect of the present disclosure.

FIG. 6B is an exemplary HAADF-STEM image showing the bilayer having an AB (3R) stacking configuration according to at least one aspect of the present disclosure.

FIG. 6C is an exemplary HAADF-STEM image showing the bilayer having a twisted stacking configuration according to at least one aspect of the present disclosure.

FIG. 6D is an exemplary fast Fourier transform (FFT) pattern corresponding to the HAADF-STEM image of FIG. 6C

FIG. 7 is an exemplary scanning electron microscope (SEM) image of the nanoribbon device with different channel lengths between the source and drain electrodes according to at least one aspect of the present disclosure.

FIG. 8A shows exemplary transfer curves of an 8 nm-width nanoribbon device with a 400 nm channel length according to at least one aspect of the present disclosure.

FIG. 8B shows exemplary output characteristics of an 8 nm-thick nanoribbon device with a 400 nm channel length at varying back-gate voltages at 300 Kelvin (K) (solid lines) and 15 K (dashed lines) according to at least one aspect of the present disclosure.

FIG. 8C shows exemplary transfer curves of nanoribbons of varying width with a 200 nm channel length under a 30 mV bias voltage at 15 K according to at least one aspect of the present disclosure.

FIG. 8D shows exemplary transfer curves of a 20 nm-thick nanoribbon device at various temperatures according to at least one aspect of the present disclosure.

FIG. 9A is an exemplary conductance map of an example device according to at least one aspect of the present disclosure.

FIG. 9B is an exemplary conductance map of an example device according to at least one aspect of the present disclosure.

FIG. 10A is an exemplary HAADF-STEM image showing a single layer MoS₂ nanoribbon according to at least one aspect of the present disclosure (scale: 5 nm).

FIG. 10B is an exemplary HAADF-STEM image of a portion of the single layer MoS₂ nanoribbon imaged in FIG. 10A at a higher magnification according to at least one aspect of the present disclosure (scale: 1 nm).

FIG. 10C is an exemplary HAADF-STEM image of a different portion of the single layer MoS₂ nanoribbon imaged in FIG. 10A at a higher magnification according to at least one aspect of the present disclosure (scale: 1 nm).

FIG. 11 shows a schematic representation of an example process for forming a twisted bilayer nanoribbon according to at least one aspect of the present disclosure.

FIG. 12 is an exemplary SEM image showing an example of a twisted stack bilayer MoS2 nanoribbon according to at least one aspect of the present disclosure.

To facilitate understanding, identical reference numerals have been used, where possible, to designate identical elements that are common to the figures. It is contemplated that elements and features of one example may be beneficially incorporated in other examples without further recitation.

### DETAILED DESCRIPTION

The present disclosure generally relates to bilayer metal dichalcogenides, to processes for forming bilayer metal dichalcogenides, and to uses of bilayer metal dichalcogenides in devices for quantum electronics, e.g., quantum computing, quantum sensing, and quantum communication. The processes described herein enable formation of, e.g., bilayer structures such as nanoribbons. The inventors found that metal nanoparticles can drive the width of the bilayer down to about 20 nm or less (such as about 8 nm or less). The bilayer structures can be incorporated into devices such as field effect transistors (FETs). The bilayer structures exhibit, e.g., width-dependent Coulomb-blockade oscillations, which can enable quantum transport at high temperatures (e.g., up to about 80 Kelvin or more). In some examples, the inventors show that quantum oscillation can be, e.g., controlled by the width of the bilayer structure and the stacking configuration of the layers in the bilayer structure. The bilayer structure, and devices incorporating the bilayer structure, enable the tunability of metal dichalcogenide QD transport features.

Reducing the width of two-dimensional materials down to quasi-1D nanostructures, called nanoribbons, adds another degree of freedom for engineering devices that take advantage of the electronic behavior of nanoribbons. However, experimental results on 2D TMD nanoribbons, especially for those with a width of 30 nm or less, are scarce due to, e.g., lack of directly synthesized materials that ensure retaining of their intrinsic properties. Current fabrication methods for monolayer TMDs rely on top-down techniques such as lithography cutting or etching on monolayer films or flakes. Recently, direct growth of monolayer MoS₂ ribbons having a width of 50-100 nm have been formed using salt-assisted growth, as well as substrate-directed or ledge-directed epitaxy processes.

Adding a second layer of a TMD provides for further abilities to tune the formed electronic structures through, e.g., interlayer stacking and twisting. However, bilayer TMD nanoribbons have not been reported until now. In some examples, bilayer TMD nanoribbons having a width from about 8 nm to about 100 nm are grown by utilizing metal-based nanoparticles. The metal-based nanoparticles can act to, e.g., control the growth of the layers and the diameter of the metal-based nanoparticles can, e.g., control the width of the layers. Quantum transport behavior is observed in these nanoribbons, enabling use of the bilayer structures in quantum electronic devices at high temperatures (e.g., greater than 4 K).

### Bilayer Metal Dichalcogenides

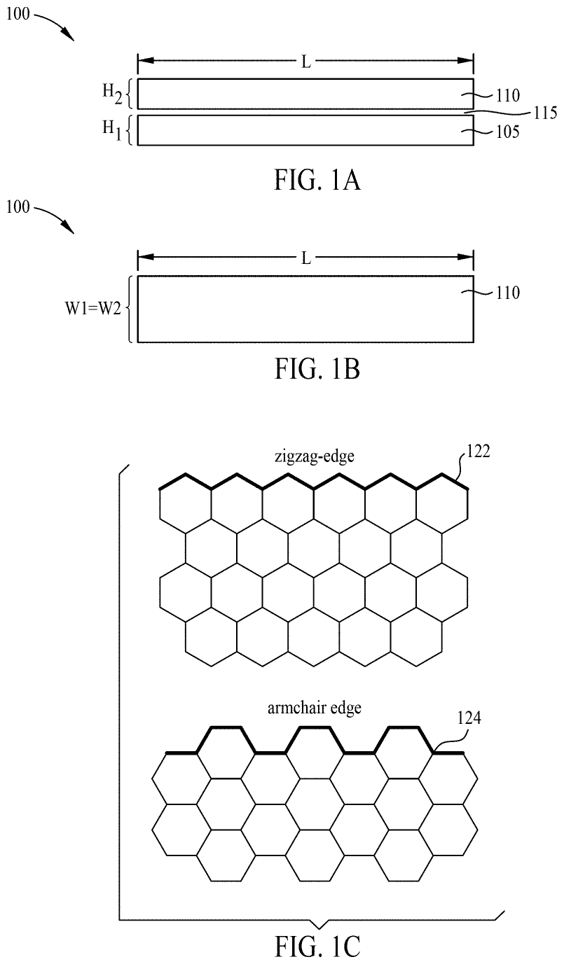

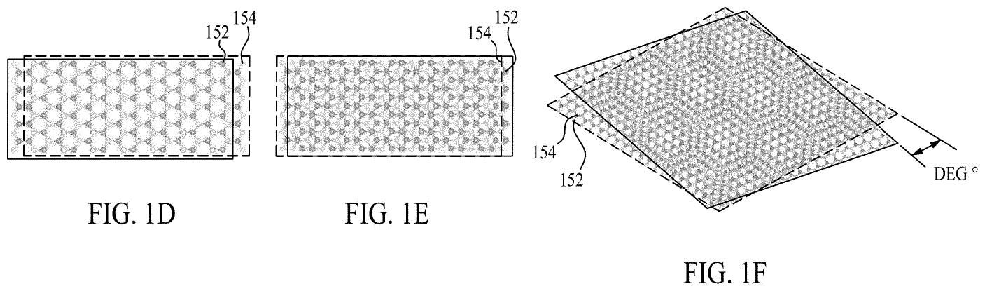

Aspects of the present disclosure generally relate to bilayer metal dichalcogenides, such as bilayer transition metal dichalcogenides. FIG. 1A shows an example bilayer structure 100 according to at least one aspect of the present disclosure As described below, these bilayer structures can be utilized with devices such as quantum electronic devices. The bilayer structure 100 includes a bottom layer 105 that includes or consists of a first metal dichalcogenide. A top layer 110 is disposed over at least a portion of the bottom layer 105. The top layer 110 includes or consists of the same metal dichalcogenide as the bottom layer or a second metal dichalcogenide. The bottom layer 105 has a thickness (H₁) and the top layer has a thickness (H₂). The thickness of the bottom layer 105 and/or the top layer 110 can be, independently, about 1 nm or less, such as about 0.8 nm or less, such as from about 0.5 nm. In some aspects, the bottom layer 105 has a thickness that is larger, smaller, or equal to the thickness of the top layer 110. The total thickness of the bilayer metal chalcogenides is determined by atomic force microscopy (AFM).

The bottom layer 105 and the top layer 110 can be spaced apart by a gap 115 (also called a van der Waals gap) having a non-zero thickness, such as about 0.5 nm or less, such as about 0.4 nm or less, such as about 0.3 nm or less, such as about 0.2 nm or less, such as about 0.1 nm or less. It is also contemplated that the bilayer structure is free of the gap 115.

The bottom layer 105 has a width (W1) and the top layer has a width (W2). The width of the bottom layer 105 and/or the top layer 110 can be, independently, 1 μm or less, such as from about 500 nm or less, such as about 400 nm or less, such as about 200 nm or less, such as from about 1 nm or more and/or about 100 nm or less, such as about 90 nm or less, such as about 80 nm or less, such as about 70 nm or less, such as about 60 nm or less, such as about 50 nm or less, such as about 40 nm or less, such as about 30 nm or less, such as about 20 nm or less, such as about 15 nm or less, such as about 10 nm or less, such as about 9 nm or less, such as about 8 nm or less, such as about 7 nm or less, such as about 6 nm or less, such as about 5 nm or less, such as about 4 nm or less, such as about 3 nm or less, such as about 2 nm or less, such as about 1 nm or less. In some aspects, the width of the bottom layer 105 and/or the top layer 110 can be, independently, about 1 nm to about 40 nm, such as from about 2 nm to about 35 nm, such as from about 5 nm to about 30 nm, such as from about 6 nm to about 25 nm, such as from about 8 nm to about 20 nm, such as from about 10 nm to about 15 nm. In some aspects, the bottom layer 105 has a width that is larger, smaller, or equal to the width of the top layer 110. The width of the individual layers, e.g., the bottom layer 105, the top layer 110, and the total width of the bilayer structure 100 is determined by scanning electron microscopy (SEM).

As stated above, the bottom layer 105 includes or consists of a first metal dichalcogenide, and the top layer 110 includes or consists of a second metal dichalcogenide. In some aspects, the first and/or second metal dichalcogenide is a transition metal dichalcogenide. The first metal dichalcogenide and the second metal dichalcogenide can be the same or different. The first and/or the second metal dichalcogenide can include MoS₂, MoSe₂, MoTe₂, WS₂, WSe₂, WTe₂, and combinations thereof.

The bottom layer 105 can be in the form of a ribbon or nanoribbon. The top layer 110 can be in the form of a ribbon or nanoribbon. Ribbons and Nanoribbons are substantially planar structures. As used herein, the term “ribbon” refers to an elongated structure, that is, a structure with a length-to-width ratio of greater than 500, optionally greater than 1000. As used herein, the term “nanoribbon” refers to a ribbon with at least one dimension on the nanoscale, for example, a ribbon having a width from about 1 nm to 500 nm or from about 1 nm to 100 nm.

In at least one aspect, the bottom layer 105 is in the form of a single nanoribbon and/or the top layer 110 is in the form of a single nanoribbon. The nanoribbon(s) can have a length-to-width ratio greater than about 1000, such as from about 1000 to 20000 such as from about 5000 to about 10000 as determined by SEM.

At least a portion of the nanoribbon(s) have a substantially uniform edge configuration as determined by high-angle annular dark-field scanning transmission electron microscopy (HAADF-STEM). In an example, as shown in FIG. 1C, the substantially uniform edge configuration can include a zigzag edge 122, an armchair edge 124, or a combination thereof as determined by HAADF-STEM.

In the bilayer structure, e.g., the bilayer nanoribbons, the bottom layer 105 and the top layer 110 can be oriented in various stacking configurations. FIGS. 1D-1F show example stacking configurations of the bilayer nanoribbons. The stacking configuration is determined by HAADF-STEM. Specifically, FIG. 1D shows an AA′ (2H) stacking configuration, FIG. 1E shows an AB (3R) stacking configuration, and FIG. 1F shows a twisted stacking configuration (e.g., a Moire pattern). In FIGS. 1D-1F, the metal atom is represented by numeral 152 and the chalcogen atom is represented by numeral 154.

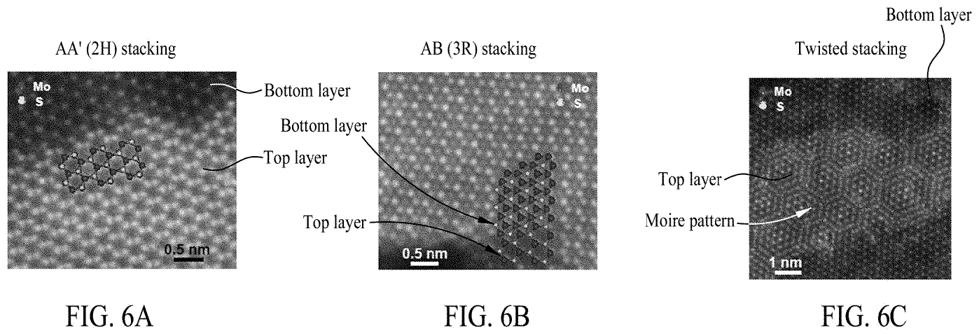

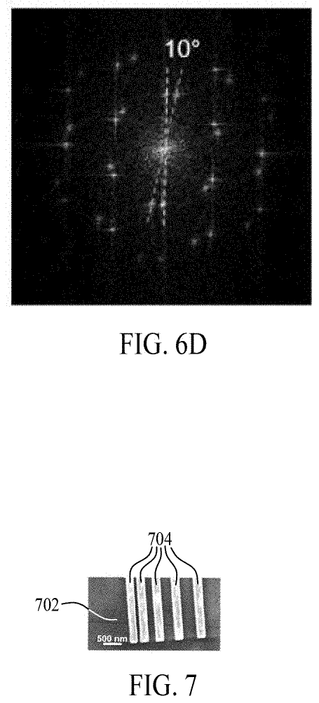

With respect to the twisted stacking configuration shown in FIG. 1E, an interlayer twist angle (deg.) between the two layers of the bilayer structure can be controlled so that, e.g., different electronic structures can be obtained according to the angle. The interlayer twist angle can be from about 1° to about 20°, such as from about 2° to about 18°, such as from about 4° to about 16°, such as from about 6° to about 14°, such as from about 8° to about 12°. It is contemplated that the interlayer twist angle can be larger or smaller. The interlayer twist angle is measured by fast Fourier transform (FFT) from the HAADF-STEM. FIGS. 6A-6C, described below, show exemplary HAADF-STEM images of the AA′ (2H) stacking configuration shown in FIG. 1D, the AB (3R) stacking configuration shown in FIG. 1E, and the twisted stacking configuration shown in FIG. 1F. The bilayer structure formed by processes described herein can have an AA′ (2H) stacking configuration, an AB (3R) stacking configuration, a twisted stacking configuration, or combinations thereof. FIG. 6D shows a FFT pattern from the HAADF-STEM in FIG. 6C, in which two sets of hexagonally arranged patterns correspond to the top and bottom layer, respectively, and the rotation angle between them is the twisted angle of the two layers.

The various stacking configurations can be controlled by the growth conditions. With respect to forming a bilayer in a twisted stacking configuration, any suitable method can be used such as manually stacking one single layer nanoribbon on the top of another single layer nanoribbon by rotating at certain angles as described below and in the Examples section.

As a non-limiting illustration for forming a bilayer nanoribbon in a twisted stacking configuration, a first single layer nanoribbon disposed on a film (e.g., poly(methyl methacrylate) (PMMA) film) is positioned above a substrate having a second single layer nanoribbon disposed thereon. The position of the first single layer nanoribbon versus the second single layer nanoribbon can be parallel or substantially parallel as determined by, e.g., an optical microscope. The film having the first single layer nanoribbon disposed thereon is then rotated greater than about 0° and less than about 180°, such as 1° to about 45°, such as from about 5° to about 30°, such as from about 10° to about 20°. In some aspects, the film is rotated from about 2° to about 18°, such as from about 4° to about 16°, such as from about 6° to about 14°, such as from about 8° to about 12°. After the film having the first single layer nanoribbon disposed thereon is rotated, the film is then placed on the substrate having the second single layer nanoribbon disposed thereon. The film can then be removed by, e.g., immersion in a suitable solvent such as acetone for about 1 h or more, such as about 5 h to about 24 h, such as about 10 h to about 15 h, to form the bilayer nanoribbon structure in a twisted stacking configuration on the substrate.

In some aspects, the bilayer nanoribbon structure in a twisted stacking configuration can have an interlayer twist angle that is greater than about 0° and less than about 180°, such as 1° to about 45°, such as from about 5° to about 30°, such as from about 10° to about 20°. In some aspects, the film is rotated from about 2° to about 18°, such as from about 4° to about 16°, such as from about 6° to about 14°, such as from about 8° to about 12°.

### Processes for Forming Bilayer Metal Dichalcogenide Structures

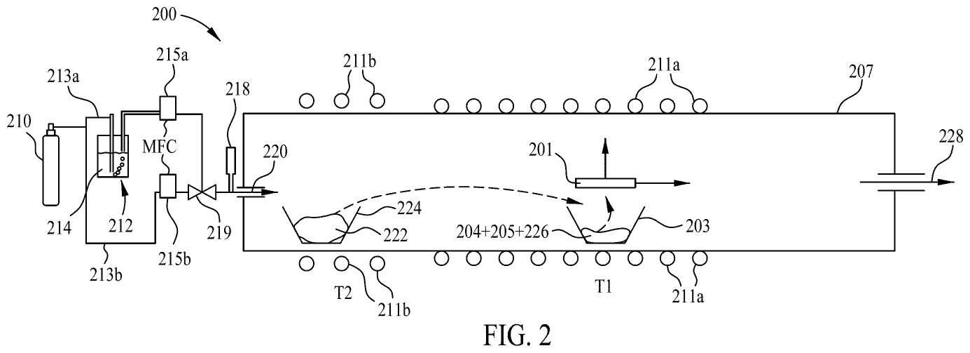

The present disclosure also generally relates to processes for forming bilayer metal dichalcogenide structures. FIG. 2 shows an example apparatus 200 useful for forming the bilayer structures described herein. The apparatus 200 is a non-limiting illustration only. Modifications and alterations of the apparatus 200 are contemplated.

The apparatus 200 includes a reaction chamber 207 such as a chemical vapor deposition chamber. The reaction chamber 207 is coupled to a gas tank 210 via a line 213a and a line 213b. The gas tank 210 includes a carrier gas, such as a non-reactive gas, such as He, Ar, Kr, Ne, Xe, N₂, or combinations thereof. Line 213b is coupled to the reaction chamber 207 via line 217 and an inlet 220, such that the carrier gas, e.g., Ar, can be flowed into the reaction chamber 207. A bubbler 212 containing water 214 is located along the line 213a. Here, the carrier gas enters the bubbler 212 and forms a moisturized carrier gas (e.g., a mixture of carrier gas and water, e.g., Ar+H₂O). The mixture of carrier gas and water (e.g., in the form of a vapor) can then be flowed into the reaction chamber 207 via the line 217 and the inlet 220.

Line 213a can be coupled to line 213b, as shown, by a junction/valve 219 such that the gases flowing through lines 213a, 213b enter the reaction chamber 207 via the inlet 220 and the line 217. Alternatively, line 213a exiting the bubbler 212 can be coupled directly to the reaction chamber 207 instead of the junction/valve 219, such that the gas flowing through line 213a and the gas flowing through line 213b enter the reaction chamber via different inlets.

Along each of the lines 213a, 213b are mass flow controllers 215a, 215b. The mass flow controllers 215a, 215b are utilized to, e.g., measure and/or control the amount of liquid/gas flowing through the lines 213a, 213b. A dew point hygrometer 218 is coupled to the line 217 and is utilized to measure the moisture content of the gas(es) entering the reaction chamber 207. As an example, the moisture content of the gas(es) entering the reaction chamber 207 can be controlled by adjusting the flow rate ratio of carrier gas (FR_{C}) flowed through line 213b and the flow rate of moisturized carrier gas (FR_{C+H2O}) flowed through line 213a: FR_{C+H2O}/(FR_{C}+FR_{C+H2O}) using the mass flow controllers 215a, 215b. Gas(es) can exit the reaction chamber 207 via outlet 228.

During operation, e.g., deposition of metal dichalcogenide layer(s), a substrate 201 is disposed within the reaction chamber 207. As shown in FIG. 2, a first tray 203 having a salt 204, a metal 205, and a first precursor 226 comprising Mo, W, or a combination thereof disposed therein is also located in the reaction chamber 207. A second tray 224 is utilized to hold a second precursor 222 comprising a chalcogen atom (e.g., S, Se, Te, or combinations thereof). The first tray 203 and the second tray 224 can be of any shape and size. The term “tray” is not particularly limited, and suitable trays include but are not limited to, weigh boats, crucibles, flasks, or other vessels that can withstand the temperature excursions of the processes disclosed herein.

Heating can be performed with a heating mechanism, for example, with one or more heating wires 211a, 211b above and/or below the first tray 203 and second tray 224 such as in an oven or other suitable apparatus as can be known in the art. The heating wires 211a, 211b can provide different amounts of heat to different locations of the chamber, as described below. For example, the heating wires 211a can be operated at a first temperature, T1, and the heating wires 211b can be operated at a second temperature, T2.

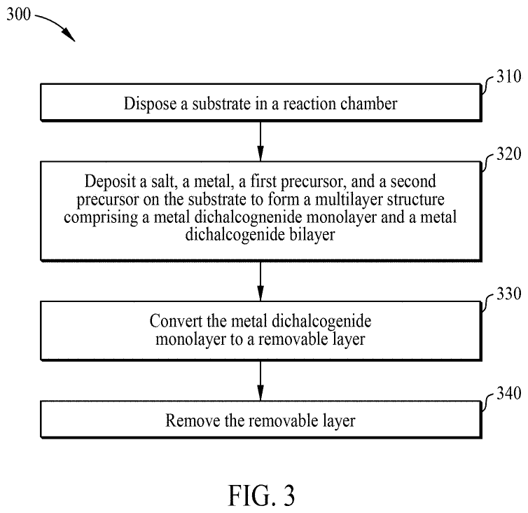

FIG. 3 shows selected operations of an example process 300 of forming a bilayer structure, e.g., a bilayer metal dichalcogenide, according to at least one aspect. The process 300 can be formed utilizing the apparatus 200 shown in FIG. 2.

The process 300 includes disposing or positioning a substrate 201 in a reaction chamber 207, such as a quartz tube, at operation 310. The substrate 201 can be covered by a mask 202 having a patterned shape. According to some aspects, the substrate 201 can be a non-reactive material suitable for use according to the processes described herein. Examples of substrates useful according to the present disclosure include, but are not limited to, substrates comprising or consisting of SiO₂, Si, c-sapphire, fluorophlogopite mica, SrTiO₃, hexagonal boron nitride (h-BN), or combinations thereof. It should be understood that while a SiO₂ substrate is used herein as an exemplary substrate, any suitable substrate can be used in addition to or instead of the same.

The process further includes depositing a salt, a metal, a first precursor, and a second precursor on the substrate 201 to form a multilayer structure comprising a bottom layer and a top layer. The multilayer structure can be deposited by chemical vapor deposition (CVD) methods.

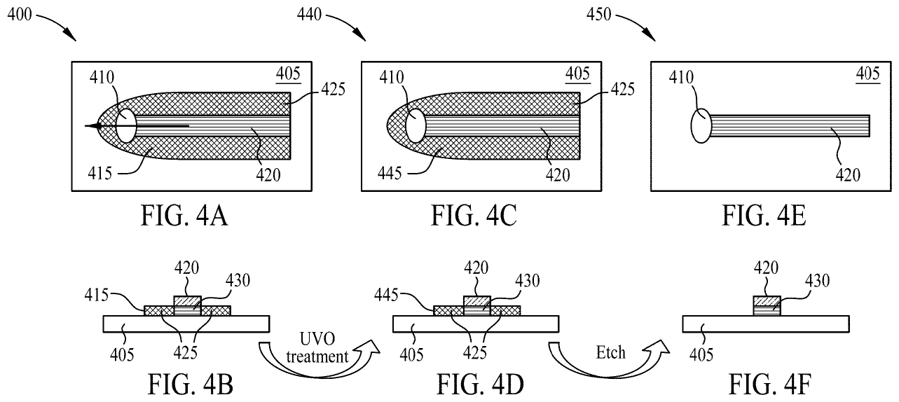

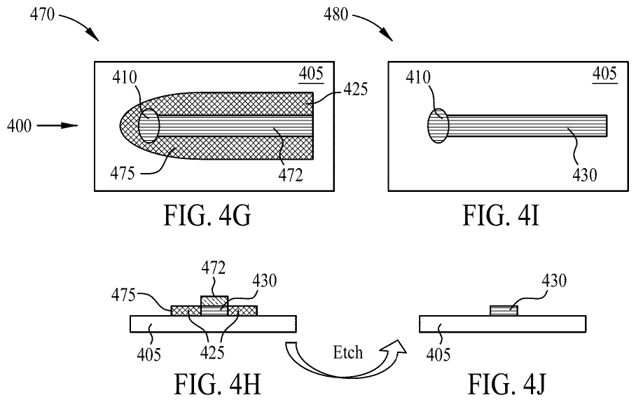

The bottom layer is disposed over at least a portion of the substrate, and the top layer is disposed over at least a portion of the bottom layer. The top layer includes a metal dichalcogenide and the bottom layer includes a metal dichalcogenide, the metal dichalcogenides being the same or different. FIG. 4A and FIG. 4B show a top view and a cross-sectional view, respectively, of the bilayer structure formed during operation 320. In FIG. 4A, the arrow indicates the growth direction of the structure. The bilayer structure 400 includes a bottom layer 415 (also referred to as a monolayer) and a top layer 420 (also referred to another monolayer) terminated by the metal nanoparticle 410. The top layer 420 can include the metal nanoparticle 410 (e.g., metal 205). As shown in the cross-sectional view FIG. 4B of bilayer structure 400, the bottom layer 415 includes an unexposed portion 430 (i.e., the portion of the bottom layer 415 having the top layer 420 disposed thereon) and an exposed portion 425 (i.e., the portion of the bottom layer 415 that does not have the top layer 420 disposed thereon).

The metal dichalcogenide ribbons, e.g., MoS₂ ribbons, formed in operation 320 can have a length of less than about 1 mm, such as less than about 0.7 mm. The metal nanoparticle 410 controls the width of the top layer 420 grown. For example, when an Ni nanoparticle is utilized to grow MoS₂ on the substrate 405, operation 320 can result in a bottom layer MoS₂ that is wider than the top layer MoS₂.

In some aspects, the bottom layer 415 has a width that is about 5 μm or less, such as about 2 μm or less, such as about 1 μm or less, and the top layer 420 (e.g., the bilayer structure) has a width of about 500 nm or less. The width of the top layer 420 can be that described above with respect to bilayer structure 100.

In some aspects, the salt 204 can include, but is not limited to, sodium salts and potassium salts, such as NaBr, NaCl, KBr, KCl, and combinations thereof. It should be understood that while NaBr is used herein as an exemplary salt, any suitable salt can be used in addition to or instead of the same. As used herein, the term “salt” refers to an electrically neutral ionic compound having cation(s) and anion(s).

The metal 205 can be a transition metal, such as Ni, Fe, or a combination thereof. The metal 205, which can be in the form of a particle, e.g., a nanoparticle, promotes growth of the structure comprising metal dichalcogenides. For example, the metal 205, in the form of a particle, promotes both heterogeneous nucleation of a bottom layer and homoepitaxial tip growth of a top layer via vapor-liquid-solid (VLS) mechanism, where the width of the top layer can be controlled by the particle diameter of the metal particle. In this example, both the bottom layer and the top layer is or includes a metal dichalcogenide.

Reactants for operation 320 include the first precursor 206 comprising Mo, W, or a combination thereof (e.g., a metal oxide) and the second precursor 222 comprising S, Se, Te, or combinations thereof. At least one of the layers of the plurality of TMD layers formed, includes the Mo, W, or combinations thereof, and the S, Se, Te, or combinations thereof. In some examples, the formed bilayer structure includes a top layer comprising a transition metal dichalcogenide and a bottom layer comprising a transition metal dichalcogenide.

As an example of operation 320, the substrate 201 is positioned above the first tray 203. The first tray 203, having the salt 204, the metal 205, and the first precursor 206 disposed therein, can be heated at a first temperature (Ti), and the second tray 224, having the second precursor 222 disposed therein, can be heated at a second temperature (T2) to deposit the salt 204 (e.g., NaBr), the metal 205 (e.g., Ni), the first precursor 206 (such as a metal oxide, such as a MoO₂ powder), and the second precursor 222 (e.g., a chalcogen, such as sulfur powder) on the substrate 201. The second tray 224 can be located in the apparatus 200 upstream of the first tray 203 relative to the flow of carrier gas and/or water through inlet 220. According to some aspects, heating can be performed with a heating mechanism, for example, with one or more heating wires 211a above and/or below the first tray 203, and one or more heating wires 211b above and/or below the second tray 224, such as in an oven or other suitable apparatus as can be known in the art. After a suitable time period, the multilayer structure is formed on the substrate.

During operation 320, the second tray 224 is heated to the second temperature, T2, under a flow of a carrier gas (e.g., a non-reactive gas), a flow of a carrier gas and water (H₂O), or a combination thereof. The carrier gas, carrier gas and H₂O, or both, is flown through inlet 220.

According to some aspects, the first temperature, T1, can be from about 600° C. to about 900° C., such as from about 650° C. to about 850° C., such as from about 700° C. to about 800° C., such as from about 740° C. to about 800° C., such as about 750° C. or about 770° C. According to at least one aspect, the first temperature can be achieved by ramping the temperature, for example, by ramping the temperature from room temperature to the first temperature. For example, according to some aspects, the first temperature can be achieved by ramping the temperature from room temperature to the first temperature at a rate from about 10° C./minute to about 70° C./minute, such as about 20° C./minute to about 40° C./minute. As used herein, the term “room temperature” refers to a temperature from about 15° C. to about 25° C. In some aspects, the second temperature, T2, is from about 50° C. to about 350° C., such as from 100° C. to about 300° C., such as from about 150° C. to about 250° C., such as about 175° C. to about 225° C. Alternatively, and according to some aspects, the second temperature can be from about 250° C. to about 650° C., such as from about 300° C. to about 600° C., such as from about 350° C. to about 550° C., such as about 450° C. According to at least one aspect, the second temperature can be achieved by ramping the temperature, for example, by ramping the temperature from room temperature to the second temperature. For example, according to some aspects, the second temperature can be achieved by ramping the temperature from room temperature to the second temperature at a rate from about 10° C./minute to about 70° C./minute, such as about 20° C./minute to about 40° C./minute.

In at least one aspect, the time period for deposition of the multilayer structure in operation 320 is from about 1 minute or more and/or about 10 h or less, such as about 1 min to about 1 hour, such as from about 1 to about 30 minutes, such as from about 1 to about 15 minutes, such as from about 3 and 15 minutes.

During operation 320, and according to some aspects, the carrier gas, the mixture of carrier gas and water, or both, are flowed into the reaction chamber through inlet 220 described above. The H₂O concentration in the mixture of carrier gas and water (FR_{C+H2O}) can be about 100 ppm or more and/or about 5,000 ppm or less, such as from about 250 ppm to about 4,000 ppm, such as from about 500 ppm to about 3,000 ppm, such as from about 1,000 ppm to about 2,500 ppm, such as from about 1,500 ppm to about 2,000 ppm. The H₂O concentration can be controlled by adjusting the flow rate of carrier gas (FR_{C}), the flow rate of the carrier gas and water (FR_{C+H2O}), and/or the following flow rate ratio:

FR_{C+H2O}/(FR_{C}+FR_{C+H2O})

In some aspects, the flow rate ratio FR_{C}/(FR_{C}+FR_{C}+H₂O) is from about 0.01:1 to about 0.5:1, such as from about 0.05:1 to about 0.25:1, such as from about 0.1:1 to about 0.2:1.

Operation 320 can include one or more of the following parameters:

(a) A flow rate of the carrier gas (FR_{C}) that can be about 10 sccm to about 100 sccm, such as from about 40 sccm to about 80 sccm for a 1×1 cm² to 5×5 cm²-sized substrate.

(b) A flow rate of the carrier gas+H₂O (FR_{C}+H₂O) that can be about 1 sccm to about 100 sccm, such as from about 10 sccm to about 40 sccm for a 1×1 cm² to 5×5 cm²-sized substrate.

(c) A weight ratio of salt 204 to first precursor 206 that can be about 0.01:1 to about 1:1, such as from about 0.05:1 to about 1:1, such as from about 0.1:1 to about 1:1.

(d) A weight ratio of metal 205 to the first precursor 206 that can be about 0.02:1 to about 1:1, such as from about 0.05:1 to about 1:1, such as from about 0.1:1 to about 1:1, such as such as from about 0.2:1 to about 1:1.

(e) A weight ratio of first precursor 206 to second precursor 222 can be about 1:1 to about 200:1, such as from about 20:1 to about 150:1, such as from about 50:1 to about 100:1.

The process 300 further includes converting at least a portion of the bilayer structure 400 (e.g., the bottom layer 415) to a removable portion 445 (e.g., an etchable portion, such as an oxidized portion) at operation 330. The removable portion 445 of the bottom layer can be a metal oxide. The conversion of operation 330 can be performed by subjecting at least a portion of the bottom layer 415 to ultraviolet-ozone (UVO) treatment.

In some non-limiting examples, the UVO treatment can include disposing the bilayer structure 400 in a UVO-cleaner having a UV light. The substrate having the bilayer structure 400 deposited thereon (for example, by a CVD process as described herein) can be placed in a UVO-cleaner at a certain distance from the UV light such that a UVO intensity is provided to the bilayer structure 400 sufficient to oxidize a desired portion, e.g., the bottom layer 415. According to some aspects, the distance between the UV light and the desired portion of the bilayer structure 400 can be from about 0.1 cm to about 5 cm, such as from about 0.5 cm to 3.2 cm. According to some aspects, the UVO treatment may be performed at a temperature from about 20° C. to about 200° C. for a time from about five minute and two hours, and optionally for a time of between about eight minutes and one hour.

FIG. 4C and FIG. 4D show a top view and a cross-sectional view, respectively, of the multilayer structure 440 formed by operation 330, respectively. For example, when the bottom layer 415 is MoS₂, at least a portion of the MoS₂ of the bottom layer 415 can be converted to MoO₃ via treatment with ozone and UV light, while the top layer 420, which includes MoS₂, remains unchanged or substantially unchanged. For example, exposed portions 425 of the bottom layer 415 are oxidized.

The process 300 further includes removing at least a portion of the removable portion 445 (e.g., the oxidized portion, MoO₃) of the bottom layer 415 at operation 340. FIG. 4E and FIG. 4F show a top view and a cross-sectional view, respectively, of the structure 450 following the removal process of operation 340. In an example, the top layer MoS₂ 420 and the unexposed portion 430 (e.g., un-oxidized layer MoS₂) is the bilayer structure 100 described above.

Removing at least a portion of the removable portion 445 can include etching the multilayer structure 440 such that the top layer MoS₂ 420 remains unchanged or substantially unchanged. Etching refers to any suitable subtractive manufacturing process wherein an etching agent is used to remove one or more substances from a surface. According to some aspects, etching can include subjecting the multilayer structure 440 to an etching treatment sufficient to separate the oxidized portion of the multilayer structure 440 from remaining portions (e.g., un-oxidized portions) thereof. A rinsing operation with, e.g., water, can be performed after etching to remove residual etching agent.

Etching can be performed by immersing, soaking, or otherwise subjecting the multilayer structure 440 to an etching agent. The etching agent can include a hydroxide, such as potassium hydroxide (KOH), lithium hydroxide, sodium hydroxide (NaOH), or a combination thereof. The etching agent may be provided as a solution, for example, an aqueous solution. In some aspects, the etching agent can have hydroxide concentration that is from about 0.1 M to about 10 M, such as from about 0.5 M to about 2 M, such as from about 0.75 M to about 1.5 M, such as from about 1 M to about 1.25 M.

In an illustrative, but non-limiting, example, the etching treatment may include soaking the multilayer structure having at least one oxidized portion (e.g., removable portion 445) in a hydroxide solution for a time sufficient to remove the oxidized portion. The time can be, for example, about 1 h or less, such as about 30 minutes or less, such as about 5 minutes or less, such as about 1 min or less, such as from about one second to about one minute, such as from about 10 seconds to about 30 seconds.

In some aspects, and as shown in FIGS. 4G and 4H, operation 330 can additionally, or alternatively, include oxidizing at least a portion of the bottom layer 415 and at least a portion of the top layer 420. Oxidizing by, e.g., UVO treatment, forms a multilayer structure 470 that includes an oxidized top layer 472 and oxidized portions of the bottom layer (e.g., removable portion 475). As an example, and when the bottom layer 415 and top layer 420 are MoS₂, the top layer 420 and portions of the bottom layer 415 are converted to MoO₃. The UVO treatment is described above.

In these and other aspects, and as shown in FIGS. 4I and 4J, operation 340 can additionally, or alternatively, include removing at least a portion of the removable portion 475 and removing at least a portion of the oxidized top layer 472 to form a structure 480. The structure 480 includes the unexposed portion 430, e.g., a single layer metal dichalcogenide, such as single layer MoS₂ nanoribbon, disposed over the substrate 405. As an example, the top layer MoO₃ and oxidized portions of the bottom layer (e.g., MoO₃) can include etching such that MoO₃ portions of the top and bottom layers are removed. The removal operation, such as etching, and an optional rinsing operation are discussed above.

It should be understood that while the processes for direct growth of a patterned MoS2 bilayer structure using molybdenum dioxide (MoO₂) as the first precursor 206 or metal oxide and sulfur (S) as the second precursor 222 comprising, various bilayer structures can be prepared according to the process described herein. For example, according to some aspects, the bilayer structure can include tungsten disulfide (WS₂) and/or molybdenum diselenide (MoSe₂) by using tungsten dioxide (WO₂) and/or tungsten trioxide (WO₃) as the first precursor 206 as described herein and/or by using selenium (Se) as the second precursor 222. Other suitable precursors can be used to form the metal dichalcogenide represented by the formula ME₂.

### Devices

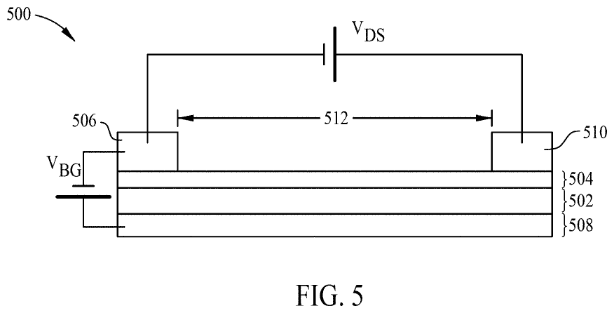

Aspects of the present disclosure also relate to devices, such as quantum devices, incorporating a bilayer structure as produced by processes herein. The devices can be characterized as electronic devices and/or optoelectronic devices. FIG. 5 shows an example device 500 incorporating a bilayer structure according to at least one aspect of the present disclosure. For example, device 500 can include a substrate 502 and a bilayer structure 504 positioned thereon. The bilayer structure 504 can be represented by bilayer structure 100 or by structure 450 when the bilayer structure is disposed over at least a portion of a substrate.

The device 500 can also include components for introducing current through the bilayer structure 504, such as a source electrode 506, a gate electrode 508 (e.g., a back-gate electrode) for supplying a potential or charge to the source electrode 506 and a drain electrode 510 for receiving a current from the source electrode 506 based on the charge supplied to the source electrode 506. A channel 512 between the source electrode 506 and the drain electrode 510 can have a length of about 1 μm or less, such as about 500 nm or less, such as about 50 nm to about 450 nm, such as about 100 nm to about 400 nm, such as from about 150 nm to about 350 nm, such as from about 200 nm to about 300 nm. The source electrode 506 and the drain electrode 510, can be made of, or include, independently, any suitable material such as graphene, glassy carbon, copper, nickel, silver, aluminum, gold, platinum, palladium, bismuth, or combinations thereof. The gate electrode 508, can be made of, or include, any suitable material such as highly doped-silicon, graphene, carbon nanotube, or combinations thereof.

In some examples, the device 500 can operate as, or otherwise include, a field effect transistor (FET) such as a back-gate field effect transistor (BG-FET). BG-FETs are types of transistors that utilize an electric field to control the flow of current through at least three terminals or electrodes—a gate, a source, and a drain. In operation, a voltage can be applied to the back-gate electrode (VBG), which alters the conductivity between the drain electrode and the source electrode. A drain-source voltage (VDs) can be applied to, e.g., create electrical current between the source and drain electrodes. Manipulation of the various voltages and currents enables movement of electrons through various components of the device.

### Processes for Using the Device

The present disclosure is also generally related to using a device (e.g., device 500) incorporating a bilayer structure described herein. Such a device has applications in, e.g., sensors, bio-imaging, batteries, electrochemical water splitting, wastewater treatment, supercapacitors, photodetectors, and optoelectronic applications. The devices can be operated at temperatures greater than the state-of-the-art, e.g., greater than about 1 K, such as from about 4 K to about 100 K, such as from about 4K to about 80 K, such as from about 4 K to about 60 K.

In some aspects, the device, e.g., device 500, can be utilized to control electrons, e.g., controlling a spin, a charge, or both. Here, and in some aspects, a voltage can be applied to the gate electrode to tune the energy level of the MoS₂ nanoribbon to allow or block electron(s) tunneling in from the source electrode to the nanoribbon and/or tunneling out from the nanoribbon to the drain electrode.

In at least one aspect, a process of using device 500 includes cooling the device to a temperature of about 1 K or more, such as from about 4 K to about 100 K, such as from about 4K to about 80 K, such as from about 4 K to about 60 K. The process further includes applying a voltage to the gate electrode (e.g., gate electrode 508). The voltage applied to the gate electrode can be from about −80 V to about 80 V, such as from about −60 V to about 60 V, such as from about −40 V to about 40 V, such as from about −20 V to about 20 V. In at least one aspect, the voltage applied to the gate electrode is from about −80 V to about 0 V, such as from about −70 V to about −10 V, such as from about −60V to about −20 V, such as from about −50 V to about −30 V. In another aspect, the voltage applied to the gate electrode is from about 0 V to about 80 V, such as from about 10 V to about 70 V, such as from about 20 V to about 60 V, such as from about 30 V to about 50 V. A source-drain bias (e.g., about 50 mV or less, such as from about 10 mV to about 50 mV, such as from about 20 mV to about 40 mV) can also be applied. The voltage applied to the gate electrode controls a flow of an electron between one or more of the source electrode 506, the drain electrode 510, the bottom layer of the bilayer structure (e.g., bottom layer 105), and/or the top layer of the bilayer structure (e.g., top layer 110). The voltage applied to the gate electrode can also tune the energy level of the bilayer structure to allow and/or block electron tunneling in from the source electrode to a portion of the bilayer structure and/or tunneling out from a portion of the bilayer structure to the drain electrode. In some aspects, a magnetic field can be applied to the device to control a spin of the electron. The magnetic field applied can be from about 1 T to about 14 T, such as from about 2 T to about 12 T, such as from about 4 T to about 10 T, such as from about 6 T to about 8 T.

The following examples are put forth so as to provide those of ordinary skill in the art with a complete disclosure and description of how to make and use aspects of the present disclosure, and are not intended to limit the scope of aspects of the present disclosure. Efforts have been made to ensure accuracy with respect to numbers used (e.g. amounts, dimensions, etc.) but some experimental errors and deviations should be accounted for.

### EXAMPLES

### 1. Characterization

The as-synthesized MoS₂ ribbons were characterized using QUANTA™ FEG 650 scanning electron microscope (SEM) from FEI and operated at 10 kV. High-angle annular dark-field scanning transmission electron microscopy (HAADF-STEM) images were collected by employing a Nion UltraSTEM equipped with a probe aberration corrector (the convergence angle was 31 mrad) operating at 60 kV. Atomic force microscopy was performed using a Bruker Dimension Icon atomic force microscope. Interlayer twist angle was determined by fast Fourier transform from an HAADF-STEM image.

The samples for HAADF-STEM characterization were prepared using a wet transfer process. Poly(methyl methacrylate) (PMMA) 495A4 (MicroChem) is first spun onto the SiO₂/Si substrate with monolayer crystals at 3500 r.p.m. for 60 s. The PMMA-coated substrate was then floated on 1 M KOH solution, which etched the silica epi-layer, leaving the PMMA film with the ribbons floating on the solution surface. The film was rinsed in deionized water for several times to remove residual KOH. The washed film was scooped onto a 20 nm-thick QUANTIFOIL holey carbon film (˜2 μm hole size) supported by a 200-mesh Au TEM grid, which was subsequently soaked in acetone for 12 h to remove PMMA and get a clean sample surface. The transferred samples were finally annealed at 200° C. in vacuum to get rid of the solvent.

### 2. Example Bilayer Synthesis

MoS₂ ribbons were synthesized through a CVD method conducted in a tube furnace system equipped with a 1″ quartz tube. In the experimental setup, two separate carrier gas (e.g., Ar) gas lines are connected to the tube furnace. One line directly goes to the reaction chamber at a certain flow rate (called FR_{Ar}) while the other goes through a small bubbler, containing ˜2 ml of deionized water to produce moisturized Ar. The moisturized Ar is flowed into the reaction at a certain flow rate (called FR_{Ar+H2O}). Therefore, the moisture content in the moisturized Ar carrier gas can be controlled by adjusting the ratio of FR_{Ar+H2O}/(FR_{Ar}+FR_{Ar+H2O}), and measured by a dew point hygrometer (Easidew Online, Rotronic Instrument Corp.) mounted near the inlet to the reaction chamber.

In an example growth run, ˜1.5 mg of MoO₂+NaBr+Ni mixture at a certain weight ratio of 1:0.05:0.1, was heated to ˜770° C., and meanwhile, a ˜0.1 g of S, placed upstream of the MoO₂, was heated to 200° C. The gas flow ratio of FR_{Ar+H2O}/(FR_{Ar}+FR_{Ar+H2O}) is ˜10%, e.g., 72 sccm of FR_{Ar} combined with 8 sccm of FR_{Ar+H2O}, which accounts for 3000 ppm of moisture content as measured by a Dew point transmitter mounted at the gas inlet of the tuber. A 285 nm SiO₂/Si substrate, cleaned by acetone and isopropanol, was used as the growth substrate, placed face-down on the top of the precursor. The typical growth time at ˜770° C. is ˜3 minutes. The as-grown ribbons were treated by UV-Ozone (Jelight Company Inc.) at about room temperature in air for ˜8 min, followed by soaking in a ˜1 M KOH solution for ˜10 sec and rinsing in deionized water to clean residual KOH.

### 3. Example Device Fabrication and Electrical Property Measurements.

Electron-beam (E-beam) lithography patterning was performed by Nanobeam n64 Electron Beam Writer system, the electron beam was operated at an accelerating voltage of 80 kV. Metal electrodes of Ti/Au (10 nm/50 nm) were deposited on top of MoS₂ nanoribbons in Angstrom EvoVac Deposition system, the deposition vacuum level is lower than 5×10⁻⁷ Torr. Transport measurements at variable temperature were performed in a CTI-Cryogenics Model 22 Refrigerator using a Keysight B1500A Semiconductor Device Parameter Analyzer.

### 4. Example Stacking Configurations

Stacking configurations of the bilayer structures were investigated. FIGS. 6A-6C show exemplary HAADF-STEM images of the bilayer structure in various stacking configurations. Specifically, FIG. 6A shows the bilayer in an AA′ (2H) stacking configuration, FIG. 6B showing the bilayer in an AB (3R) stacking configuration, and FIG. 6C shows the bilayer in a twisted stacking configuration. The interlayer twist angle was determined to be about 10° according to the FFT pattern (FIG. 6D) corresponding to the HAADF-STEM image (FIG. 6C).

5. Electrical Performance of an Example Bilayer MoS₂ nanoribbon-based FET Device

A back-gate field effect transistor (BG-FET) using a Ti/Au as source and drain electrodes were fabricated to investigate the electrical properties of the bilayer MoS₂ nanoribbons. FIG. 7 shows an exemplary SEM image of a device incorporating bilayer MoS₂ nanoribbons 702, where the source and drain electrodes 704 are separated by different channel lengths.

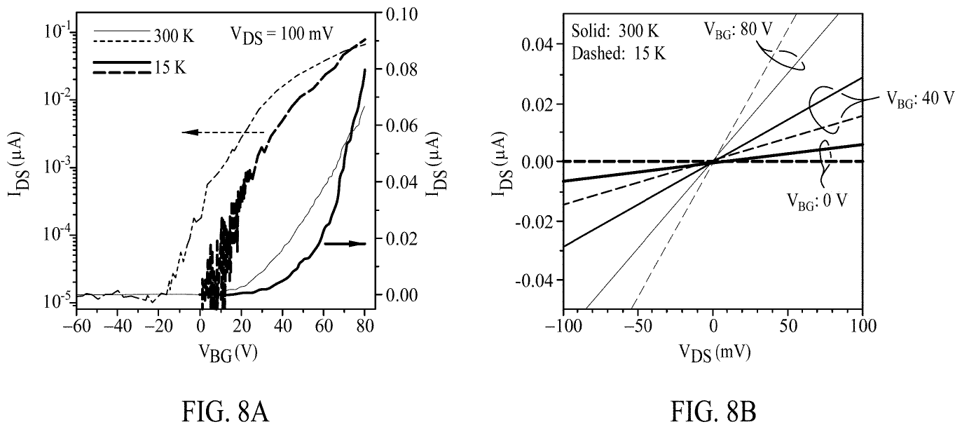

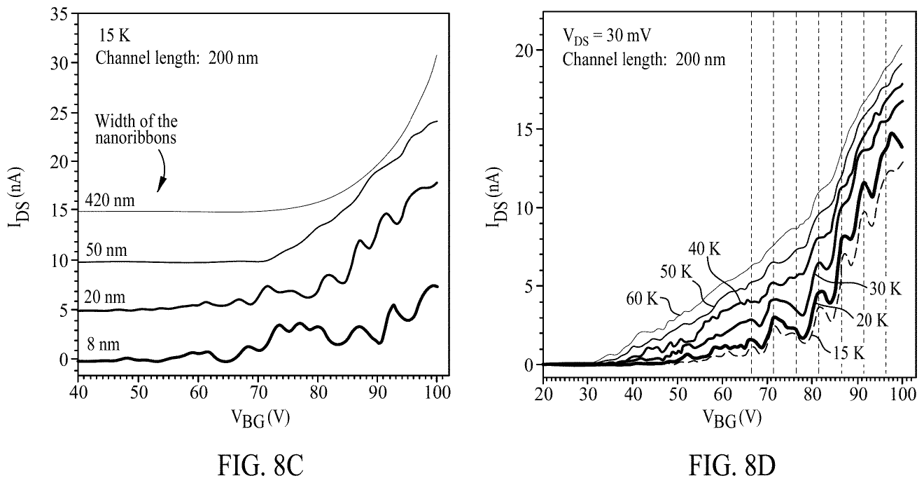

FIG. 8A shows exemplary transfer curves of an ˜8-nm wide nanoribbon measured at temperatures 15 K and 300 K, where the drain-source current (I_{DS}) is plotted against the back-gate voltage (VBG). The channel length, e.g., the length between the source and drain electrodes, was about 400 nm. The device incorporates a 8-nm wide bilayer MoS₂ nanoribbon. For this example, a 100 mV bias voltage was applied to the device. The data indicates that the device shows typical n-type behavior with an ON/OFF ratio of about 10⁴.

FIG. 8B shows exemplary output characteristics of the same device at varying back-gate voltages at 300 K (solid lines) and 15 K (dashed lines), where the drain-source current (I_{DS}) is plotted against the drain-source voltage (V_{DS}). The channel length of the device was about 400 nm. The linear output curves, even at 15 K, indicate very good ohmic contact of the Ti/Au on the nanoribbons.

FIG. 8C shows exemplary transfer curves for BG-FETs on bilayer MoS₂ nanoribbon with different widths (about 8 nm, about 20 nm, about 50 nm, and about 420 nm) at a temperature of ˜15 K, where the drain-source current (I_{DS}) is plotted against the back-gate voltage (VBG). The channel length between the source and drain electrodes for each device was about 200 nm. For this example, a 30 mV bias voltage was applied to each BG-FET device. Prominent periodic oscillations of the drain-source current, under a 30 mV drain-source bias, as a function of back-gate voltage are observed for the nanoribbon having a width of about 8 nm and the nanoribbon having a width of about 20 nm. This periodic oscillation in the transfer curves indicated the quantum dot behavior of the nanoribbons, where the periodic oscillation can be attributed to a single electron transition due to a Coulomb blockade.

FIG. 8D shows exemplary transfer curves for the BG-FET incorporating the ˜20 nm wide bilayer MoS₂ nanoribbons with the channel length between the source and drain electrodes being ˜200 nm, illustrating the temperature dependent Coulomb blockade oscillation, where the vertical dashed lines indicate periodic oscillation peaks. Prominent periodic oscillations of the drain-source current, under a 30 mV drain-source bias, as a function of back-gate voltage are observed. The data indicates that the Coulomb blockade oscillations are observable at temperatures from about 15 K to about 60 K. Notably, Coulomb blockade oscillations in TMD structures have only been observed at temperatures below 4 K. Thus the data demonstrates that bilayer structures described herein function at much higher temperatures relative to conventional TMD structures.

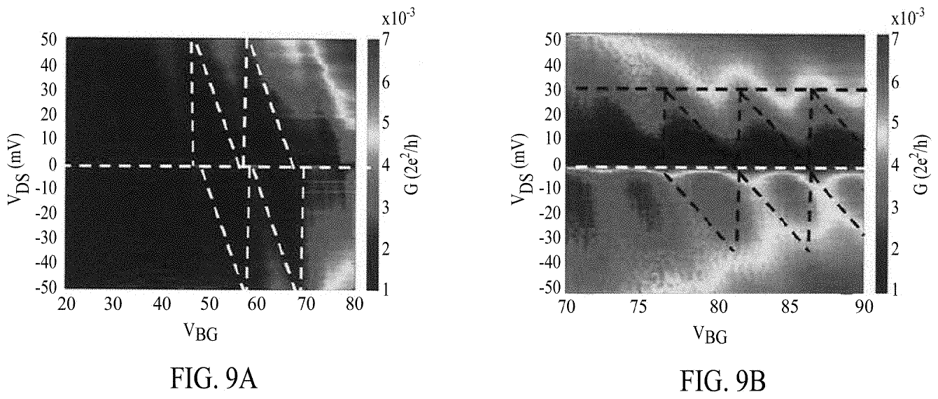

FIG. 9A and FIG. 9B show conductance maps, as a function of drain-source voltage (V_{DS}) and back-gate voltage (V_{BG}), at 15 K of two exemplary BG-FET devices incorporating ˜8 nm wide bilayer MoS₂ nanoribbons with channel lengths between source and drain electrodes of 100 nm and 200 nm respectively. The vertical dashed lines in FIGS. 9A and 9B highlight the Coulomb blockage diamonds. The data for FIGS. 9A and 9B was determined by measuring transfer curves with varying source-drain voltages and plotting a two-dimensional conductance map. The data demonstrates the quantum dot behavior of the bilayer nanoribbons. The different size of the Coulomb diamonds indicate different quantum dot behavior, e.g., charging energy, effective capacitance, etc. with different channel length.

Overall, the results demonstrate that quantum dot behavior in the bilayer TMD nanoribbons can be controlled by, e.g., the width of the nanoribbons and the length of the channel. The data also demonstrates that quantum phenomena are observed at high temperatures in bilayer TMD nanoribbons.

### 6. Example Single Layer Synthesis

Single layer MoS₂ ribbons were synthesized through a CVD method conducted in a tube furnace system equipped with a 1″ quartz tube. In the experimental setup, two separate carrier gas (e.g., Ar) gas lines are connected to the tube furnace. One line directly goes to the reaction chamber at a certain flow rate (called FR_{Ar}) while the other goes through a small bubbler, containing ˜2 ml of deionized water to produce moisturized Ar. The moisturized Ar is flowed into the reaction at a certain flow rate (called FR_{Ar+H2O}). Therefore, the moisture content in the moisturized Ar carrier gas can be controlled by adjusting the ratio of FR_{Ar+H2O}/(FR_{Ar}+FR_{Ar+H2O}), and measured by a dew point hygrometer (Easidew Online, Rotronic Instrument Corp.) mounted near the inlet to the reaction chamber. In an example growth run, ˜1.5 mg of MoO₂+NaBr+Ni mixture at a certain weight ratio of 1:0.05:0.1, was heated to ˜770° C., and meanwhile, a ˜0.1 g of S, placed upstream of the MoO₂, was heated to 200° C. The gas flow ratio of FR_{Ar+H2O}/(FR_{Ar}+FR_{Ar+H2O}) is ˜10%, e.g., 72 sccm of FR_{Ar} combined with 8 sccm of FR_{Ar+H2O}, which accounts for 3000 ppm of moisture content as measured by a Dew point transmitter mounted at the gas inlet of the tuber. A 285 nm SiO₂/Si substrate, cleaned by acetone and isopropanol, was used as the growth substrate, placed face-down on the top of the precursor. The typical growth time at ˜770° C. is ˜3 minutes.

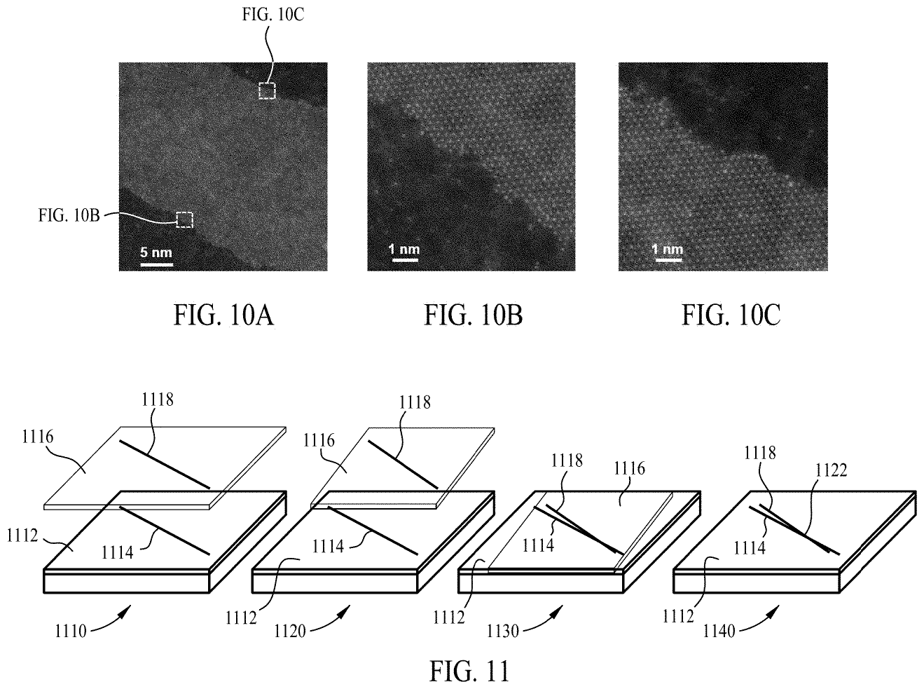

The as-grown ribbons were treated by UV-Ozone (Jelight Company Inc.) at about room temperature in air for, followed by soaking in a KOH solution and rinsing in deionized water to clean residual KOH. FIGS. 10A-C are exemplary HAADF-STEM images showing the single layer MoS₂ nanoribbon formed at various resolutions. Specifically, FIG. 10A is a low magnification view (scale: 5 nm). FIGS. 10B and 10C are atomic resolution views (scale: 1 nm) of the portions of the MoS₂ indicated by the boxes in FIG. 10A. The data indicates that a single layer MoS₂ was formed.

### 7. Example Formation of Twisted Bilayer Nanoribbons

FIG. 11 shows a schematic representation of an example process for forming a twisted bilayer nanoribbon according to some embodiments. At operation 1110, a single layer nanoribbon 1118 picked up by a poly(methyl methacrylate) (PMMA) film 1116 is placed at a location above a substrate 1112 having a single layer nanoribbon 1114 disposed thereon. The location of the PMMA film 1116 is parallel, or substantially parallel, to the substrate such that the single layer nanoribbon 1114 and the single layer nanoribbon 1118 are parallel, or substantially parallel, as observed by an optical microscope. The PMMA film 1116 having the single layer nanoribbon disposed thereon can be formed by spinning PMMA (e.g., PMMA 495 A4) onto a substrate such as an SiO₂ substrate with monolayer crystals at 3500 r.p.m. for ˜60 s. The PMMA-coated substrate was then floated on ˜1 M KOH solution, which etched the silica epi-layer, leaving the PMMA film 1116 with single layer nanoribbon 1118 floating on the solution surface. The film was rinsed in deionized water for several times to remove residual KOH.

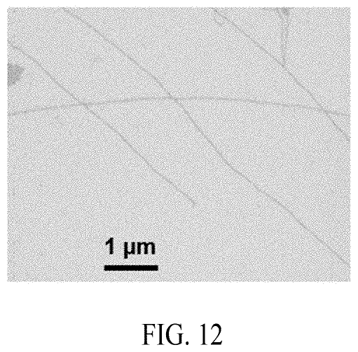

At operation 1120, the PMMA film 1116 having the single layer nanoribbon 1118 disposed thereon is rotated by a certain amount, e.g., greater than about 0° and less than about 180°. Larger or smaller angles are contemplated. After selecting a desired angle, the PMMA film 1116 having the single layer nanoribbon 1118 disposed thereon is then stacked on the substrate 1112 having the single layer nanoribbon 1114 disposed thereon at operation 1130. The PMMA film 1116 is then removed, at operation 1140, using a suitable solvent such as acetone for about 5 h to 24 h, resulting in a twisted bilayer nanoribbon 1122. FIG. 12 is an exemplary SEM image showing an example of a twisted stack bilayer MoS₂ nanoribbon. The SEM image indicates that twisted bilayer nanoribbons can be formed.

### Aspects Listing

The present disclosure provides, among others, the following aspects, each of which can be considered as optionally including any alternate aspects:

Clause 1. A device, comprising:

a gate electrode;

a substrate disposed over at least a portion of the gate electrode;

a bottom layer comprising a first metal dichalcogenide, the bottom layer disposed over at least a portion of the substrate;

a top layer comprising a second metal dichalcogenide, the top layer disposed over at least a portion of the bottom layer, the first metal dichalcogenide and the second metal dichalcogenide being the same or different; and

a source electrode and a drain electrode disposed over at least a portion of the top layer.

Clause 1. The device of Clause 1, wherein:

the bottom layer has a width of about 30 nm or less as measured by scanning electron microscopy;

the top layer has a width of about 30 nm or less as measured by scanning electron microscopy; or

both.

Clause 3. The device of Clause 1 or Clause 2, wherein:

the width of the bottom layer is about 20 nm or less;

the width of the bottom layer is about 20 nm or less; or

both.

Clause 4. The device of any one of Clauses 1-3, wherein:

the bottom layer is in the form of a single nanoribbon;

the top layer is in the form of a single nanoribbon; or

a combination thereof.

Clause 5. The device of Clause 4, wherein:

when the bottom layer is in the form of a single nanoribbon, at least a portion of the single nanoribbon of the bottom layer has a substantially uniform edge configuration as determined by HAADF-STEM;

when the top layer is in the form of a single nanoribbon, at least a portion of the single nanoribbon of the top layer has a substantially uniform edge configuration as determined by HAADF-STEM; or

a combination thereof.

Clause 6. The device of Clause 5, wherein the substantially uniform edge configuration includes a zigzag edge, an armchair edge, or a combination thereof as determined by HAADF-STEM.

Clause 7. The device of any one of Clauses 1-6, wherein a stacking configuration of the bottom layer and the top layer is an AA′ (2H) stacking configuration, an AB (3R) stacking configuration, or a twisted stacking configuration, or combinations thereof as determined by HAADF-STEM.

Clause 8. The device of Clause 7, wherein when the stacking configuration includes a twisted stacking configuration, an interlayer twist angle between the bottom layer and the top layer is from about 1° to about 20° as determined by fast Fourier transform from an HAADF-STEM image.

Clause 9. The device of any one of Clauses 1-8, wherein a distance between the source electrode and the drain electrode is about 1 μm or less.

Clause 10. The device of Clause 9, wherein the distance is about 500 nm or less.

Clause 11. The device of any one of Clauses 1-10, wherein the first metal dichalcogenide and the second metal dichalcogenide are the same.

Clause 12. The device of any one of Clauses 1-11, wherein:

the first metal dichalcogenide comprises MoS₂, MoSe₂, MoTe₂, WS₂, WSe₂, WTe₂, or combinations thereof;

the second metal dichalcogenide comprises MoS₂, MoSe₂, MoTe₂, WS₂, WSe₂, WTe₂, or combinations thereof; or

both.

Clause 13. The device of any one of Clauses 1-12, wherein the first metal dichalcogenide, the second metal dichalcogenide, or both, comprises Mo.

Clause 14. The device of any one of Clauses 1-13, wherein the first metal dichalcogenide, the second metal dichalcogenide, or both, comprises MoS₂.

Clause 15. A process, comprising:

positioning a substrate in a chamber; and

thermally depositing a salt, a metal particle, a first precursor comprising Mo, W, or a combination thereof, and a second precursor comprising S, Se, Te, or combinations thereof on the substrate to form a multilayer structure, the multilayer structure comprising:

a bottom layer disposed over at least a portion of the substrate, the bottom layer comprising a first metal dichalcogenide; and

a top layer disposed over at least a portion of the bottom layer, the top layer comprising a second metal dichalcogenide.

Clause 16. The process of Clause 15, wherein the metal particle is located at one end of the top layer.

Clause 17. The process of Clause 15 or Clause 16, further comprising:

converting an exposed portion of the bottom layer to an oxidized portion; and

removing the oxidized portion of the bottom layer.

Clause 18. The process of any one of Clauses 15-17, further comprising flowing water and a carrier gas into the chamber while depositing the multilayer structure.

Clause 19. A process, comprising:

cooling a device of any one of Clauses 1-14 at a temperature of about 1 K to about 80 K;

applying a voltage to the gate electrode to control a flow of an electron between one or more of the source electrode, the drain electrode, the bottom layer, or the top layer.

Clause 20. The process of Clause 19, wherein a magnetic field is applied to the device to control a spin of the electron.

Aspects described herein relate to bilayer metal dichalcogenides, to processes for forming bilayer metal dichalcogenides, and to uses of bilayer metal dichalcogenides in devices for quantum electronics, e.g., quantum computing, quantum sensing, and quantum communication. The bilayer metal dichalcogenides can be in the form of nanoribbons, e.g., bilayer TMD nanoribbons, and can be formed with controllable width by utilizing metal particles. The metal particle can play a dual role in, e.g., promoting heterogeneous nucleation of the bottom layer as well as nucleation and homoepitaxial growth of the top layer through the VLS growth mechanism, in which the diameter of the metal particle defines the width of the layer. The nanoribbons enable quantum transport behavior at temperatures, e.g., up to about 60 K. The bilayer TMD nanoribbons can be incorporated into devices such as FET devices.

As is apparent from the foregoing general description and the specific aspects, while forms of the aspects have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa, e.g., the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “a layer” include aspects comprising one, two, or more layers, unless specified to the contrary or the context clearly indicates only one layer is included.

While the foregoing is directed to aspects of the present disclosure, other and further aspects of the disclosure may be devised without departing from the basic scope thereof, and the scope thereof is determined by the claims that follow.

What is claimed is:

1. A device, comprising:
a gate electrode;
a substrate disposed over at least a portion of the gate electrode;
a bottom layer comprising a first metal dichalcogenide, the bottom layer disposed over at least a portion of the substrate;
a top layer comprising a second metal dichalcogenide, the top layer disposed over at least a portion of the bottom layer, the first metal dichalcogenide and the second metal dichalcogenide being the same or different; and
a source electrode and a drain electrode disposed over at least a portion of the top layer.

2. The device of claim 1, wherein:
the bottom layer has a width of about 30 nm or less as measured by scanning electron microscopy;
the top layer has a width of about 30 nm or less as measured by scanning electron microscopy; or
both.

3. The device of claim 2, wherein:
the width of the bottom layer is about 20 nm or less;
the width of the top layer is about 20 nm or less; or
both.

4. The device of claim 1, wherein:
the bottom layer is in the form of a single nanoribbon;
the top layer is in the form of a single nanoribbon; or
a combination thereof.

5. The device of claim 4, wherein:
when the bottom layer is in the form of a single nanoribbon, at least a portion of the single nanoribbon of the bottom layer has a substantially uniform edge configuration as determined by HAADF-STEM;
when the top layer is in the form of a single nanoribbon, at least a portion of the single nanoribbon of the top layer has a substantially uniform edge configuration as determined by HAADF-STEM; or
a combination thereof.

6. The device of claim 5, wherein the substantially uniform edge configuration includes a zigzag edge, an armchair edge, or a combination thereof as determined by HAADF-STEM.

7. The device of claim 1, wherein a stacking configuration of the bottom layer and the top layer is an AA′ (2H) stacking configuration, an AB (3R) stacking configuration, or a twisted stacking configuration, or combinations thereof as determined by HAADF-STEM.

8. The device of claim 7, wherein when the stacking configuration includes a twisted stacking configuration, an interlayer twist angle between the bottom layer and the top layer is from about 1° to about 20° as determined by fast Fourier transform from an HAADF-STEM image.

9. The device of claim 1, wherein a distance between the source electrode and the drain electrode is about 1 μm or less.

10. The device of claim 1, wherein the distance is about 500 nm or less.

11. The device of claim 1, wherein the first metal dichalcogenide and the second metal dichalcogenide are the same.

12. The device of claim 1, wherein:
the first metal dichalcogenide comprises MoS₂, MoSe₂, MoTe₂, WS₂, WSe₂, WTe₂, or combinations thereof;
the second metal dichalcogenide comprises MoS₂, MoSe₂, MoTe₂, WS₂, WSe₂, WTe₂, or combinations thereof; or
combinations thereof.

13. The device of claim 1, wherein the first metal dichalcogenide, the second metal dichalcogenide, or both, comprises Mo.

14. The device of claim 1, wherein the first metal dichalcogenide, the second metal dichalcogenide, or both, comprises MoS₂.

15. A process, comprising:
positioning a substrate in a chamber; and
thermally depositing a salt, a metal particle, a first precursor comprising Mo, W, or a combination thereof, and a second precursor comprising S, Se, Te, or combinations thereof on the substrate to form a multilayer structure, the multilayer structure comprising:
a bottom layer disposed over at least a portion of the substrate, the bottom layer comprising a first metal dichalcogenide; and
a top layer disposed over at least a portion of the bottom layer, the top layer comprising a second metal dichalcogenide.

16. The process of claim 15, wherein the metal particle is located at one end of the top layer.

17. The process of claim 15, further comprising:
converting an exposed portion of the bottom layer to an oxidized portion; and
removing the oxidized portion of the bottom layer.

18. The process of claim 15, further comprising flowing water and a carrier gas into the chamber while depositing the multilayer structure.

19. A process, comprising:
cooling a device at a temperature of about 1 K to about 80 K, the device comprising:
a gate electrode;
a substrate disposed over at least a portion of the gate electrode;
a bottom layer comprising a first metal dichalcogenide, the bottom layer disposed over at least a portion of the substrate;
a top layer comprising a second metal dichalcogenide, the top layer disposed over at least a portion of the bottom layer, the first metal dichalcogenide and the second metal dichalcogenide being the same or different; and
a source electrode and a drain electrode disposed over at least a portion of the top layer; and
applying a voltage to the gate electrode to control a flow of an electron between one or more of the source electrode, the drain electrode, the bottom layer, or the top layer.

20. The process of claim 19, wherein a magnetic field is applied to the device to control a spin of the electron.
